(19) United States
(12) Patent Application Publication
(10) Pub. No.: US 2026/0157160 A1
(43) Pub. Date: Jun. 4, 2026

(54) METHODS OF MANUFACTURING AN ELECTRONIC CIRCUIT TO REDUCE SHORTS AND CRACKING BETWEEN METAL CONTACTS

(71) Applicant: Micron Technology, Inc., Boise, ID (US)

(72) Inventors: Sok Han Wong, Boise, ID (US); Lingyu Kong, Singapore (SG); Juan Li, Singapore (SG)

(21) Appl. No.: 19/404,559

(22) Filed: Dec. 1, 2025

Related U.S. Application Data
(60) Provisional application No. 63/726,770, filed on Dec. 2, 2024.

(51) Int. Cl. H10W 20/00; H10B 41/20; H10B 43/20

(52) U.S. Cl. CPC H10W 20/0595; H10B 41/20; H10B 43/20; H10W 20/075; H10W 20/082

(57) ABSTRACT

A method includes forming one or more layers of an electronic circuit. The one or more layers include a first metal contact isolated by a trench filled with a first dielectric material from a second metal contact. The method further includes forming a first recess in the first metal contact and forming a second recess in the second metal contact. The method further includes forming a cap layer by filling the first recess and the second recess with a second dielectric material. The method further includes removing a portion of the cap layer to form a first top surface of the one or more layers. The method further includes removing the first dielectric material from the trench to form an open trench between the first metal contact and the second metal contact.

### RELATED APPLICATION

This application claims the benefit of U.S. Provisional Patent Application No. 63/726,770, filed December 2, 2024, the entire content of which is incorporated by reference herein.

### TECHNICAL FIELD

Embodiments of the disclosure relate generally to memory sub-systems, and more specifically, relate to methods of manufacturing an electronic circuit to reduce shorts and cracking between metal contacts.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIGS. 1A-G are cutaway schematic representations illustrating a method of manufacturing an electronic circuit to reduce shorts between metal contacts, in accordance with some embodiments of the present disclosure.

FIGS. 2A-B are cutaway schematic representations illustrating an electronic circuit, in accordance with some embodiments, of the present disclosure.

FIGS. 3A-B are flow diagrams of example methods of manufacturing an electronic circuit to reduce shorts between metal contacts, in accordance with some embodiments of the present disclosure.

FIG. 4A illustrates an example computing system that includes a memory sub-system in accordance with some embodiments of the present disclosure.

FIG. 4B is a block diagram of a memory device in communication with a memory sub-system controller of a memory sub-system, according to an embodiment.

### DETAILED DESCRIPTION

Aspects of the present disclosure are directed to methods of manufacturing an electronic circuit (e.g., a memory array) while reducing the probability of shorts and cracking appearing between metal contacts of the electronic circuit. Storage devices such as solid-state drives (SSDs) may incorporate 3-dimensional (3D) NAND flash memory technology. Traditional NAND flash memory stores data in a 2-dimensional (2D) structure, where memory cells are laid out on a single layer. 3-dimensional (3D) NAND instead stacks memory cells vertically in multiple layers (hence the “3D” designation). Such vertical stacking allows for increased storage densities and greater storage capacity in a comparatively smaller physical footprint when compared to planar NAND. A key advantage of 3D NAND is its ability to continue increasing storage capacities while maintaining or even improving performance and reliability. 3D NAND technology has enabled the development of SSDs with larger capacities, faster speeds, and lower costs per unit of storage.

A 3D NAND device includes multiple memory cells stacked vertically in multiple tiers. In order to achieve higher storage capacities and/or improve performance of the device, the number of tiers within a single memory device may be increased, thus allowing for higher-capacity storage devices. However, the increase in the number of tiers also increases the overall height of the 3D NAND structure. “Height” herein refers to the size of the 3D NAND structure that is measured in the direction that is orthogonal to the layers substantially forming the structure. To limit the height of the 3D NAND structure, the thickness of each tier can be decreased.

A 3D NAND device includes metal contacts for accessing the complementary metal-oxide-semiconductor (CMOS) circuits (e.g., transistors) used for managing and/or controlling the memory arrays. The CMOS may be disposed adjacent to (e.g., beneath, etc.) a memory array, reducing the overall device size. The CMOS may control operation of memory cells in the 3D NAND device. The CMOS may select cells that are to be accessed, such as for read and/or write operations. The CMOS may regulate the power, timing and signals sent to individual memory cells, ensuring data can be stored and retrieved efficiently.

The metal contacts for accessing the CMOS may be formed in one or more layers of the 3D NAND device. For example, the metal contacts may extend through a stack of layers to reach the CMOS. In some embodiments, the metal contacts are formed by a process having various etch and/or deposition operations. Some of the operations performed may use mask layers to control etching, such as photomasks, etc. In some implementations, the metal contacts may be formed having a flared top. The flared top may be formed because of poor control of etch operations, such as from multiple etch operations using patterned mask layers. If the flared top of a metal contact is too big, the flare can contact neighboring metal contacts, causing shorts between the neighboring metal contacts, rendering those contacts nonfunctional. Additionally, the regions around the flared tops may be susceptible to cracking, such as due to stress differences between the metal contacts and dielectric layers around the metal contacts. Cracking can occur during manufacturing of the 3D NAND device or later because of thermal stresses, etc.

Aspects of the present disclosure may address the deficiencies described above and other challenges by providing methods of manufacturing a memory array to reduce shorts and cracking between metal contacts. Methods described herein may produce electronic circuits (e.g., memory devices, etc.) having fewer shorts and less susceptibility to cracking when compared to other manufacturing methods. Moreover, the methods described herein can be more efficient by reducing the number of pattern masks used when compared to other manufacturing methods.

In some embodiments, one or more layers of an electronic circuit are formed, such as by depositing alternating layers of dielectric materials (e.g., oxides or nitrides, etc.) to form a stack of layers. The layers may include electrically conductive or electrical storage layers alternating with electrically insulating layers to insulate adjacent conductive or storage layers from one another. The layers of the electronic circuit may include metal contacts formed therein. For example, the metal contacts may be for electrically coupling to a CMOS layer, such as when manufacturing of the electronic circuit is complete. Adjacent or otherwise physically proximate metal contacts may be isolated from each other by a trench filled with a dielectric material, such as silicon oxide, or another metalloid oxide, etc. In some embodiments, the trench physically separates blocks of the electronic circuit. In some examples, such as when the electronic circuit is a memory array, subsets of the metal contacts form memory array blocks. The trench separates a first block of the memory array (including a first subset of the metal contacts) from a second block of the memory array (including a second subset of the metal contacts).

In some embodiments, a recess is formed in each metal contact. The recesses may be formed using an etch process to selectively etch the metal from an adjacent dielectric or conductive layer. In some embodiments, the recesses are formed by performing a hot phosphorus etch process on the metal contacts. In some embodiments, a cap layer is formed on top of the layers. The cap layer may be formed so that subsequent etch operations do not affect the remainder of the metal of the metal contacts. For example, without the cap layer, subsequent etch operations may damage the metal contacts. However, the cap layer may protect the metal contacts during such subsequent etch operations to avoid damage. The cap layer may be formed by filling the recesses in the metal contacts with a dielectric material (e.g., silicon oxide, etc.).

In some embodiments, a portion of the cap layer is removed. Removal of the portion of the cap layer may form a top surface of the stack of layers. A planarization process (e.g., such as a chemical-mechanical planarization process) may be performed to remove the portion of the cap layer and form a substantially planar top surface. In some embodiments, the dielectric material is removed from the space between the first metal contact and the second metal contact, thus opening the trench between the first metal contact and the second metal contact. In some embodiments, the open trench separates a first block of a memory array from a second block of the memory array. A first subset of metal contacts may belong to the first block and a second subsets of metal contacts may belong to the second block.

In some embodiments, a memory array formed according to the methods described herein includes a stack of layers, such as alternating layers of oxides and nitrides, and multiple metal contacts formed within the stack of layers. The multiple metal contacts may have substantially non-flared top profiles, which may improve the structural integrity of the stack of layers and may reduce shorts between adjacent metal contacts. The metal contacts may include a detectable amount of metalloid oxide (e.g., silicon oxide, etc.) at a region adjacent to (e.g., above, etc.) the metal of the metal contacts. The detectable amount of metalloid oxide may be residual from the cap layer formed according to the methods described herein. When upper contacts are formed to electrically connect to the multiple metal contacts, the upper contacts are extended through the cap layer, but do not completely remove the cap layer. Therefore, remnants of the cap layer can be found in the upper contacts adjacent to the metal contact.

Advantages of the present disclosure include, for example, improved 3D NAND structures having fewer undesirable shorts between metal contacts. Additional advantages include, for example, improved 3D NAND structures that are less susceptible to cracking. By using the methods described herein, metal contacts in a 3D NAND device may have a substantially non-flared top, reducing the likelihood that the metal contacts will be shorted with neighboring metal contacts. Reducing the number of shorts can improve performance of a memory sub-system, leading to faster memory operations and/or decreased latency. Moreover, the substantially non-flared tops of the metal contacts allow more space for dielectric material between the metal contacts, increasing the strength of the dielectric material in that region, thus reducing the likelihood of cracking. Further, the methods described herein may reduce the number of mask layers used to manufacture the electronic circuit when compared to other methods, reducing the manufacturing time and expense accordingly. Therefore, manufacturing system throughput can be increased.

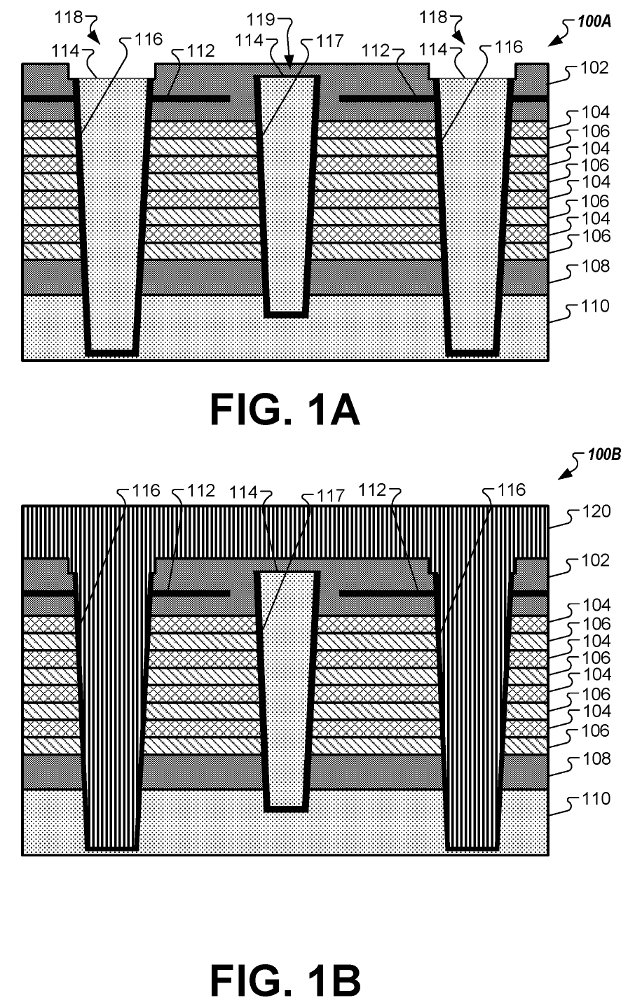

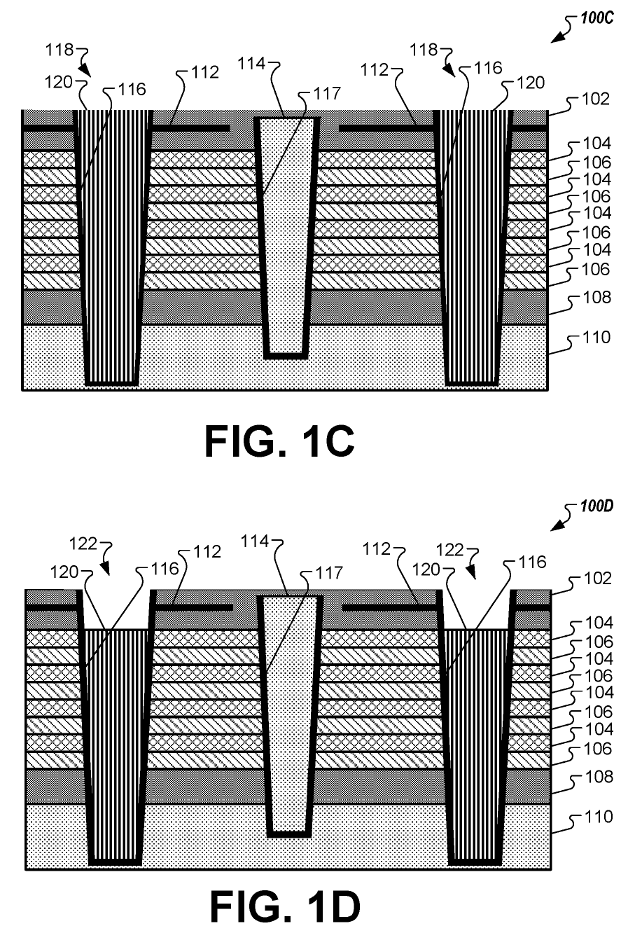

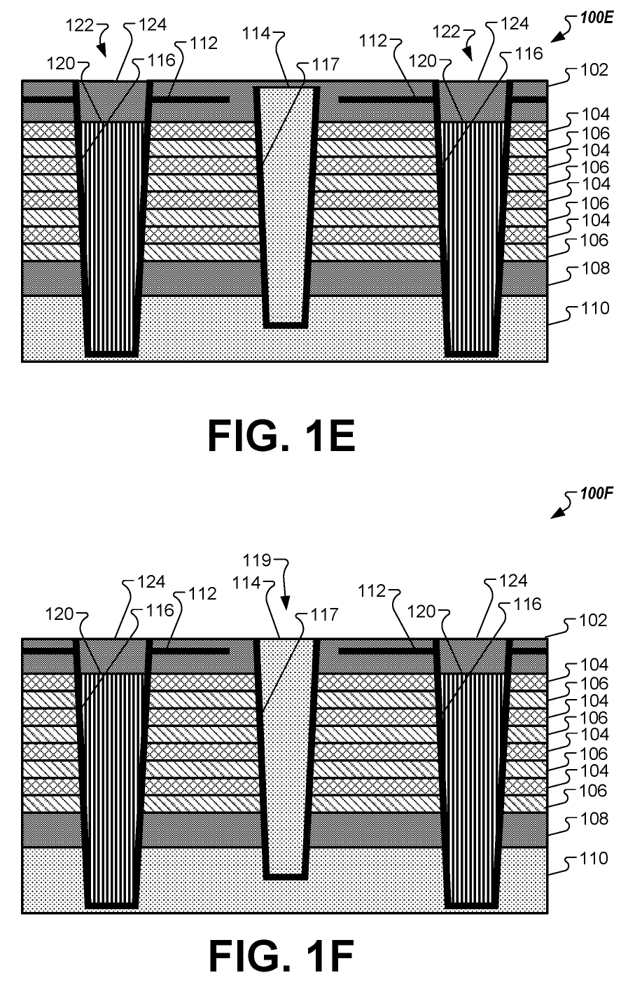

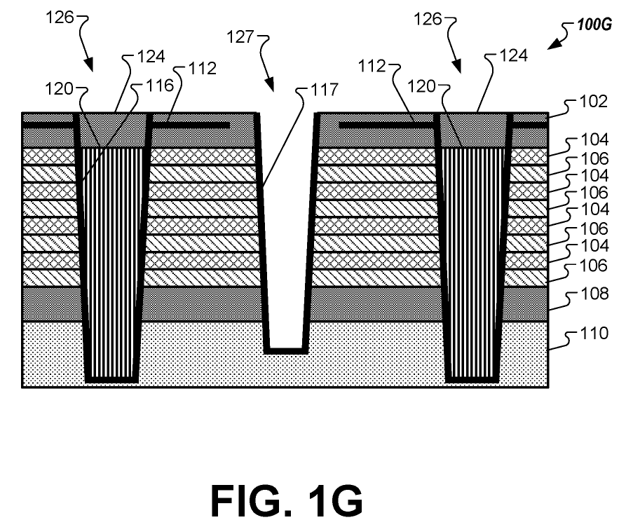

FIGS. 1A-G are cutaway schematic representations illustrating a method of manufacturing an electronic circuit (e.g., a memory array) to reduce shorts between metal contacts, in accordance with some embodiments of the present disclosure. In some embodiments, each of FIGS. 1A-G illustrate a manufacturing operation for manufacturing a memory array as described herein.

Referring to FIG. 1A, a representation of an operation 100A is shown. In some embodiments, one or more layers are formed. The layers may include oxide layers 104 (e.g., metalloid oxide layers such as silicon oxide layers, etc.) and nitride layers 106 (e.g., metalloid nitride layers such as silicon nitride layers, etc.). The oxide layers 104 and the nitride layers 106 may alternate within a stack of layers. For example, a first oxide layer 104 may be disposed on top of a first nitride layer 106, a second nitride layer 106 may be disposed on top of the first oxide layer 104, and a second oxide layer 104 may be disposed on top of the second nitride layer 106, etc. In some embodiments, the nitride layers 106 are charge-trapping layers (e.g., electrical storage layers, etc.) and the oxide layers 104 are electrically insulative layers. The oxide layers 104 may electrically insulate adjacent nitride layers 106 from each other so that any electrical charges stored in the nitride layers 106 do not migrate to adjacent nitride layers 106. In some embodiments, a top layer 102 is disposed on top of the topmost oxide layer 104. The top layer 102 may be another oxide layer (e.g., a metalloid oxide layer such as a silicon oxide layer, etc.) and may provide further insulative properties, etc. A layer 108 may be disposed beneath the bottommost nitride layer 106. The layer 108 may be an additional oxide layer and may provide further insulative properties, etc. A silicon layer 110 may be disposed beneath the layer 108. In some embodiments, the silicon layer 110 is a poly-silicon layer (e.g., a polycrystalline silicon layer, etc.). The silicon layer 110 may provide a barrier layer between a CMOS and the stack of layers 102-108. In some embodiments, a nitride layer 112 is disposed within the top layer 102. The nitride layer 112 may couple the liners 116 to one another in a same block. For example, as illustrated in FIG. 1A, the nitride layer 112 on the left side of trench 119 may couple liners 116 on a left side of trench 119 and the nitride layer 112 on the right side of trench 119 may couple liners 116 on a right side of trench 119. The nitride layer 112 may be a metalloid nitride layer (e.g., such as silicon nitride, etc.). In some embodiments, the nitride layer 112 is doped, such as with carbon. For example, and in some embodiments, the nitride layer 112 is a carbon-doped silicon nitride layer.

The layers 102-112 may be formed by multiple deposition processes. For example, a first deposition process may be performed to deposit silicon layer 110, a second deposition process may be performed to deposit layer 108, a third deposition process may be performed to deposit a first nitride layer 106, a fourth deposition process may be performed to deposit a first oxide layer 104, etc.

In some embodiments, holes 118 and/or a trench 119 are formed in the stack of layers. The holes 118 and/or trench 119 may be formed by material removal process(es), such as by etching process(es) and/or by mechanical process(es). The holes 118 and/or the trench 119 may be filled with a dielectric material 114, such as poly-silicon, etc. The dielectric material 114 may be the same material as silicon layer 110. The holes 118 may be lined with a liner 116. In some embodiments, the liner 116 is a nitride liner (e.g., a metalloid nitride liner such as silicon nitride, etc.). The trench 119 may be lined with a liner 117. In some embodiments, the liner 117 is a nitride liner. In some embodiments, recesses are formed in the top layer 102 to expose the dielectric material 114 in the holes 118. The holes 118 may be utilized for forming metal contacts as described herein. In some embodiments, the holes 118 are exposed by etching the top layer 102. For example, and in some embodiments, a mask layer is deposited on top of top layer 102. The mask layer may be made of a mask material, such as fused silica, etc. In some embodiments, the mask material is patterned, such as by a photolithography operation, etc. The top surface of top layer 102 may be etched according to the patterned mask material to expose the dielectric material 114 filling holes 118.

Referring to FIG. 1B, a representation of an operation 100B may be shown. In some embodiments, the dielectric material 114 may be removed from the holes 118 to form voids in the layers. A metal 120 may be deposited in the voids to fill the holes 118 and form metal contacts in the layers. However, further processing as described herein may be performed to make the metal contacts functional, etc. In some embodiments, the metal 120 is tungsten or a tungsten alloy. However, other metals are possible, such as copper, etc. In some embodiments, after the dielectric material 114 is removed from the holes 118, the liners 116 are replaced. For example, and in some embodiments, the nitride liners may be removed and replaced with oxide liners. Before the metal 120 is deposited into the holes 118, the holes may be lined with the oxide liner. In some embodiments, the oxide liner is a ruby oxide liner.

Referring to FIG. 1C, a representation of an operation 100C may be shown. In some embodiments, a portion of the metal 120 is removed to form a top surface of the layers. The top surface formed by removal of the portion of the metal 120 may be substantially planar. The metal 120 may be planarized, such as by a chemical-mechanical planarization (CMP) process. In some embodiments, the top portion of the deposited metal 120 is removed so that the metal in the holes 118 is flush with the top of top layer 102.

Referring to FIG. 1D, a representation of an operation 100D may be shown. In some embodiments, recesses 122 are formed in the metal 120. The recesses 122 may be formed for later formation of a cap layer within the formed recesses 122 as described herein. The recesses 122 may be formed by performing an etch process to selectively etch the metal 120. In some embodiments, the etch process etches the metal 120 without etching the top layer 102 and without etching the liners 116. In some embodiments, the recesses 122 are formed by performing a hot phosphorous etch process with respect to the metal 120. The hot phosphorous etch process may include introducing a hot solution of phosphoric acid (H₃PO₄) to the metal 120. The hot solution of phosphoric acid may have a high selectivity for the metal 120 over the top layer 102 (e.g., including a metalloid oxide, such as silicon oxide, etc.). The hot solution of phosphoric acid may be introduced to the metal 120 at an elevated temperature, such as a temperature between approximately 150 and approximately 180 degrees Celsius.

Referring to FIG. 1E, a representation of an operation 100E may be shown. In some embodiments, a cap layer 124 is formed in the recesses 122. The cap layer 124 may be formed as a protective layer for the metal 120 so that the metal 120 is not damaged by one or more subsequent etch operations, etc. The cap layer 124 may be formed by performance of a deposition operation. The cap layer 124 may include an oxide, such as a metalloid oxide (e.g., silicon oxide, etc.). The cap layer 124 may be formed with an overburden. For example, during deposition to form the cap layer 124, more than enough material to fill the recesses 122 may be deposited (e.g., extra cap layer material may be deposited). The extra material may over-run the recesses 122 and may spill over onto the top of the top layer 102.

Referring to FIG. 1F, a representation of an operation 100F may be shown. In some embodiments, a portion of the cap layer 124 is removed. The portion of the cap layer 124 may be removed by a planarization process, such as a CMP process. In some embodiments, a portion of the top layer 102 is also removed by the same process performed to remove the portion of the cap layer 124. In some embodiments, the cap layer 124 and the top layer 102 are thinned to form a substantially planar to surface. For example, the cap layer 124 and the top layer 102 may be planarized (e.g., by a CMP process, etc.) to form the substantially planar top surface. In some embodiments, removing the overburden of the cap layer 124 and/or part of the top layer 102 exposes the dielectric material 114 within the trench 119.

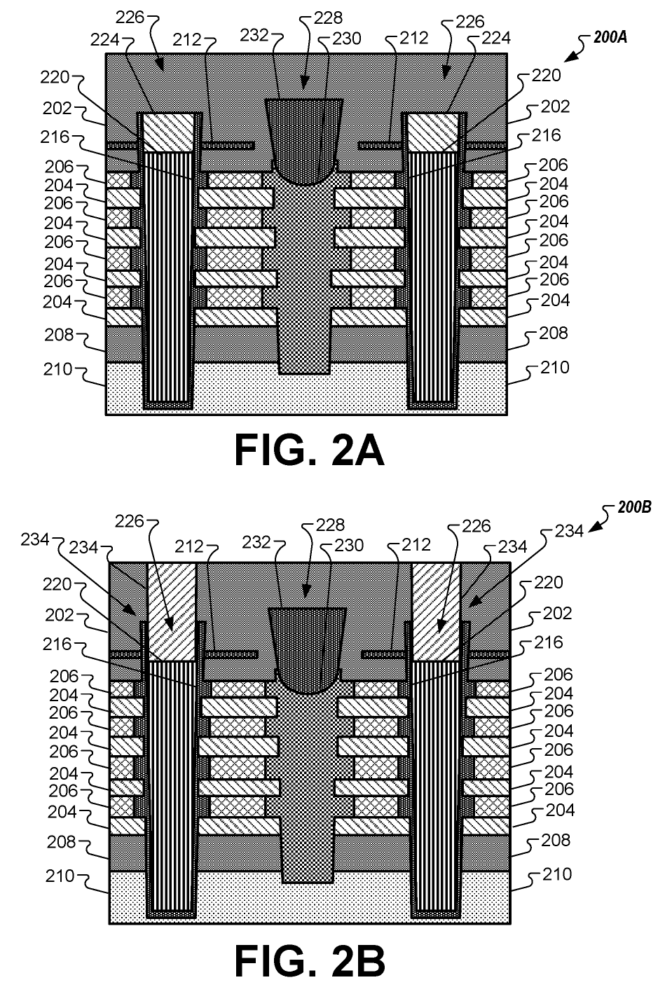

Referring to FIG. 1G, a representation of an operation 100G may be shown. In some embodiments, the dielectric material 114 within the trench 119 is removed to form an open trench 127. The open trench 127 may isolate a first metal contact 126 from a second metal contact 126. The dielectric material 114 may be removed from trench 119 using an etch process where the dielectric material 114 is selectively etched. For example, where the dielectric material 114 includes poly-silicon and the top layer 102 and cap layer 124 include an oxide (e.g., a metalloid oxide such as silicon oxide), an etch operation may be performed to selectively etch poly-silicon relative to the oxide. The metal 120 may be protected from damage during etch operation by the cap layer 124. In some embodiments, one or more additional layers and/or upper metal contacts can be formed to finish manufacturing the electronic circuit. A finished electronic circuit may be shown and described herein with respect to FIGS. 2A-B.

FIGS. 2A-B are cutaway schematic representations illustrating an electronic circuit, in accordance with some embodiments of the present disclosure. Referring to FIG. 2A, a representation of a circuit 200A having dummy contacts is shown. In some embodiments, the example electronic circuit includes multiple layers. The multiple layers may include alternating layers of conductive and/or insulating layers, etc. The multiple layers shown in FIG. 2A may correspond to the layers shown in FIGS. 1A-G. In some embodiments, a layer 208 may be formed on top of a base layer 210. The layer 208 may be an oxide layer and the base layer 210 may be a silicon layer. A series of alternating layers may be formed on top of the layer 208. For example, and in some embodiments, alternating nitride layers 206 and oxide layers 204 may be formed on top of layer 208. A top layer 202 may be formed on top of the topmost nitride layer 206. The top layer 202 may be an oxide layer. In some embodiments, a nitride layer 212 may be formed within the top layer 202. The nitride layer 212 may be a doped nitride layer, such as a carbon-doped silicon nitride layer.

In some embodiments, multiple metal contacts 226 are formed. The metal contacts 226 are formed by a metal 220 that fills a hole formed in the layers. The metal 220 may be tungsten or a tungsten alloy, in some embodiments. In some embodiments, the metal contacts 226 are each formed with a liner 216. The liners 216 may be oxide liners, such as ruby oxide liners, etc. The liners 216 may extend at least partially into the nitride layers 206. In some embodiments, as shown in FIG. 2A, the metal contacts 226 may be dummy contacts because no further electrical contact is made to the metal 220. In some embodiments, the metal 220 is capped with a cap layer 224. The cap layer 224 may be an oxide layer. In some embodiments, the metal contacts 226 form a region adjacent to (e.g., above) the metal 220. The region may have a thickness corresponding to the thickness of the cap layer 224. For example, and in some embodiments, the region may have a thickness between approximately 150 nanometers and approximately 250 nanometers. In another example, and in some embodiments, the region may have a thickness between approximately 175 nanometers and approximately 200 nanometers. At least a trace amount of oxide may be disposed adjacent to the metal 220. For example, a trace amount of oxide may be disposed within the region above the metal 220. In some embodiments, a “trace amount” of oxide refers to a minimum detectable amount of oxide. For example, the amount of oxide disposed adjacent to the metal 220 is detectable. In some embodiments, the metal contacts 226 form a substantially non-flared profile at the region above the metal 220. For example, and in some embodiments, the metal contacts 226 may form a cylindrical profile at the region above the metal 220. The non-flared nature of the profile may reduce the likelihood of shorts between neighboring metal contacts 226 and may add structural integrity to the stack of layers to reduce the chances of cracking. The region adjacent to (e.g., above) the metal 220 may form a dummy contact, in some embodiments.

In some embodiments, the metal contacts 226 are isolated from one another by a trench 228 filled with a dielectric material 230 and a cap material 232. The trench 228 may separate a first subset of metal contacts 226 (of a first block) from a second subset of metal contacts 226 (of a second block). The dielectric material 230 may be an oxide (e.g., a metalloid oxide such as silicon oxide, etc.), a nitride (e.g., a metalloid nitride such as silicon nitride, etc.), or a metalloid (e.g., silicon, etc.). In some embodiments, the dielectric material 230 extends at least partially into the nitride layers 206. The cap material 232 may be an oxide (e.g., a metalloid oxide such as silicon oxide, etc.). The dielectric material 230 may form a dished region at the top of the dielectric material 230, such as due to one or more intermediate deposition or etch operations, etc. The cap material 232 may fill the dished top region of the dielectric material 230. In some embodiments, the cap material 232 may extend at least partially through the thickness of the top layer 202.

Referring to FIG. 2B, a representation of a circuit 200B having functional contacts is shown. In some embodiments, upper metal contacts 234 contact each of the metal contacts 226. The upper metal contacts 234 may include a conductive material, such as metal or another electrical conductor. For example, the upper metal contacts 234 may include copper, tungsten, or another suitable metal alloy. In some embodiments, a transition region is formed between the metal 220 and the upper metal contacts 234. The transition region may be adjacent to the metal 220 and/or adjacent to the upper metal contacts 234. The transition region may be formed above the metal 220. The transition region may include remnants of the cap layer 224. For example, and in some embodiments, at least a trace amount of oxide (e.g., from the cap layer 224) may be found in the transition region. The trace amount of oxide found in the transition region may be a minimally detectable amount of oxide. The transition region may have a thickness between approximately 150 nanometers and approximately 250nanometers. In another example, and in some embodiments, the transition region may have a thickness between approximately 175 nanometers and approximately 200 nanometers. In some embodiments, the metal contacts 226 form a substantially non-flared profile at the transition region. For example, and in some embodiments, the metal contacts 226 may form a cylindrical profile at the transition region. The transition region may form an electrical contact between each of the metal contacts 226 and a respective upper metal contact 234.

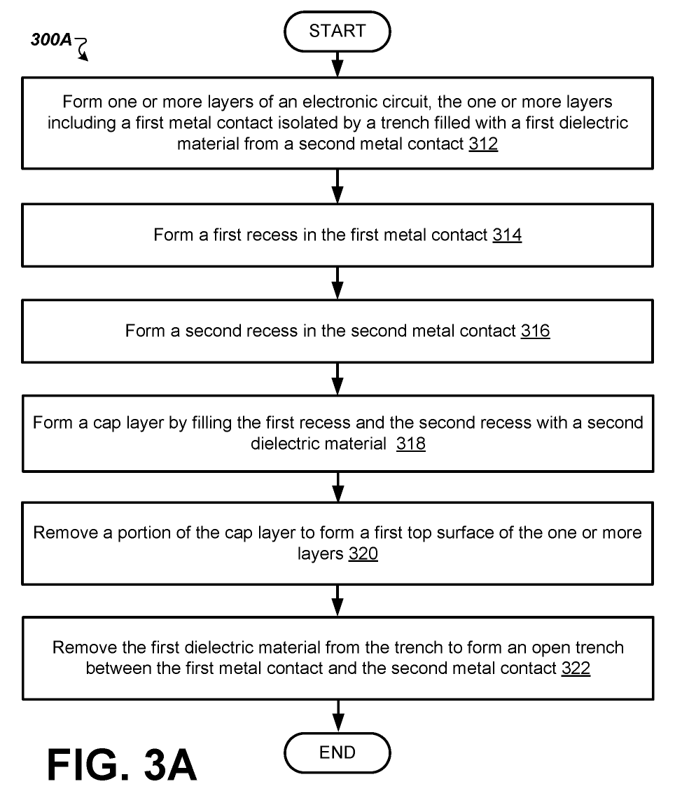

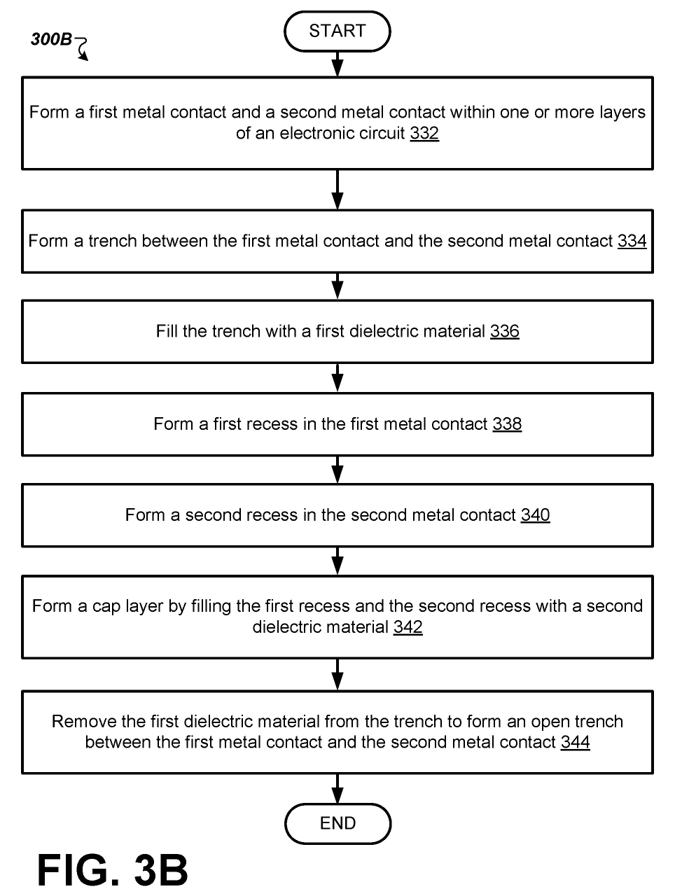

FIGS. 3A-B are flow diagrams of example methods of manufacturing an electronic circuit, in accordance with some embodiments of the present disclosure. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Referring to FIG. 3A, a flow diagram of an example method 300A is shown. At block 312, one or more layers of an electronic circuit are formed. The electronic circuit may be a memory array. The one or more layers may include one or more oxide and/or nitride layers (e.g., metalloid oxide and/or metalloid nitride layers, etc.). In some embodiments, at least some of the layers are alternating layers. For example, alternating conductive and/or insulating layers such as alternating oxide and nitride layers may be formed. The layers may be formed by multiple deposition processes, etc. In some embodiments, the one or more layers include a first metal contact isolated by a trench from a second metal contact. The trench may be filled with a first dielectric material, such as an oxide, a nitride, or poly-silicon, etc. The first metal contact may be part of a first block (e.g., a first memory block) of the electronic circuit and the second metal contact may be part of a second block of the electronic circuit. The trench may separate the first block from the second block, each block including a plurality of metal contacts.

At block 314, a first recess is formed in the first metal contact. At block 316, a second recess is formed in the second metal contact. The first and second recesses may be formed simultaneously such as by performing an etch operation with respect to the first and second metal contacts. For example, the first and second metal contacts may be simultaneously etched using an etch operation. The etch operation may include a hot phosphorous etch process. In some embodiments, the etch operation is performed to selectively etch the metal of the first and second metal contacts selective to the one or more layers. For example, a selective etch operation may be performed to etch metal (e.g., tungsten, etc.) selective to oxide and/or nitride of the one or more layers.

At block 318, a cap layer is formed by filling the first recess and the second recess with a second dielectric material. In some embodiments, the second dielectric material is the same as the first dielectric material. For example, both the first dielectric material and the second dielectric material may be oxides (e.g., metalloid oxide such as silicon oxide, etc.). In some embodiments, the cap layer is formed with an overburden. For example, an excess amount of dielectric material may be deposited to fill the first and second recesses. The excess material may be referred to as the overburden. In some embodiments, the cap layer includes an oxide, such as a metalloid oxide (e.g., silicon oxide, etc.).

At block 320, a portion of the cap layer is removed to form a first top surface of the one or more layers. In some embodiments, the cap layer is planarized, such as by a CMP process. The upper portion of the cap layer and a portion of the top layer of the one or more layers may be removed to form a substantially planar top surface. In some embodiments, the overburden of the cap layer is removed.

At block 322, the first dielectric material is removed from the trench to form an open trench between the first metal contact and the second metal contact. The open trench may later be filled with dielectric material, such as during one or more later manufacturing operations to complete the electronic circuit.

Referring to FIG. 3B, a flow diagram of an example method 300B is shown. At block 332, a first metal contact and a second metal contact are formed within one or more layers of an electronic circuit. In some embodiments, the electronic circuit is a memory array. The one or more layers may include alternating layers, such as alternating layers of oxide and nitride as described herein.

At block 334, a trench is formed between the first metal contact and the second metal contact. The trench may isolate one block from another. In some embodiments, the trench may isolate the first metal contact from the second metal contact. Each of the first metal contact and the second metal contact may be of different blocks. In some embodiments, the first metal contact is of a first block of the electronic circuit (e.g., a first block of a memory array), and the second metal contact is of a second block of the electronic circuit (e.g., a second block of the memory array). In some embodiments, a memory array includes a plurality of trenches (e.g., hundreds of trenches, thousands of trenches, etc.) isolating adjacent blocks from one another. Each of the blocks may include different numbers of metal contacts per block, depending on the block size. For example, a block may have three metal contacts, four metal contacts, or more than four metal contacts, etc.

At block 336, the trench is filled with a first dielectric material. The trench may be filled with a dielectric material such as an oxide, a nitride, and/or poly-silicon, etc.

At block 338, a first recess is formed in the first metal contact. At block 340, a second recess is formed in the second metal contact. The first and second recesses may be formed by performing an etch operation (e.g., a selective etch operation, etc.) as described herein. In some embodiments, the first recess and the second recess are formed simultaneously by the same etch operation. For example, during performance of the etch operation, the first recess and the second recess are both formed at the same time.

At block 342, a cap layer is formed by filling the first recess and the second recess with a second dielectric material. The second dielectric material may be different from the first dielectric material filling the trench. Alternatively, the second dielectric material may be the same as the first dielectric material filling the trench. In some embodiments, the second dielectric material is an oxide, such as silicon oxide, etc. The first metal contact and the second metal contact may be formed to include at least a trace amount of a metalloid oxide (e.g., silicon oxide) at a region adjacent to (e.g., above) the metal of the first metal contact and the second metal contact. For example, above the metal of the first and second metal contacts, at least a detectable amount of silicon oxide may be found. Where the cap layer is formed by a metalloid oxide, more than a trace amount of metalloid oxide may be found adjacent to the metal of the first and second metal contacts. In some embodiments, upper metal contacts may be formed to electrically couple to the first and second metal contacts. The upper metal contacts may be formed through the cap layer. Remnants of the cap layer may be found in the transition region between the metal of the first and second metal contacts and the metal of the upper metal contacts.

At block 344, the first dielectric material is removed from the trench to form an open trench between the first metal contact and the second metal contact. The open trench may later be filled with dielectric material, such as during one or more later manufacturing operations to complete the electronic circuit.

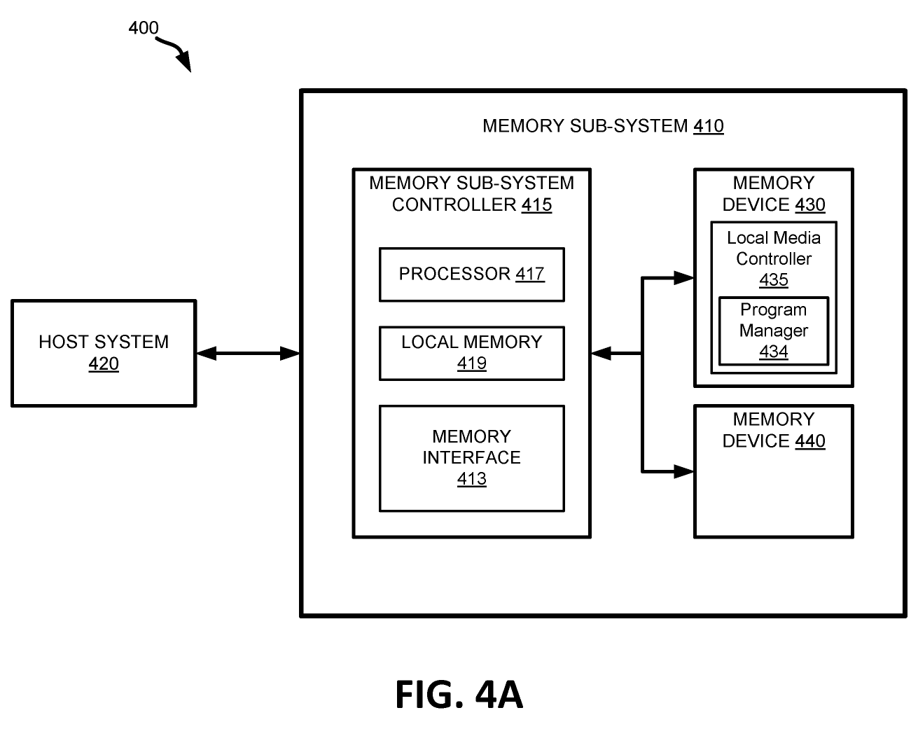

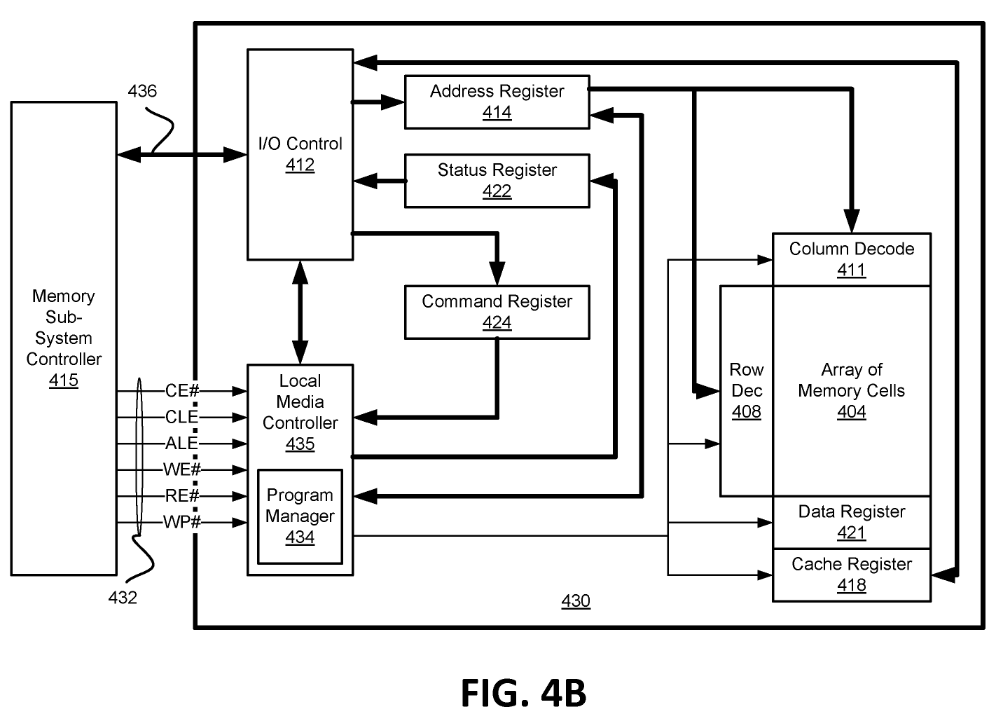

FIG. 4A illustrates an example computing system 400 that includes a memory sub-system 410 in accordance with some embodiments of the present disclosure. In some embodiments, one or more components of computing system 400 include an electronic circuit manufactured according to a method described herein above. The memory sub-system 410 can include media, such as one or more volatile memory devices (e.g., memory device 440), one or more non-volatile memory devices (e.g., memory device 430), or a combination of such.

A memory sub-system 410 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 400 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 400 can include a host system 420 that is coupled to one or more memory sub-systems 410. In some embodiments, the host system 420 is coupled to multiple memory sub-systems 410 of different types. FIG. 4A illustrates one example of a host system 420 coupled to one memory sub-system 410. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 420 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 420 uses the memory sub-system 410, for example, to write data to the memory sub-system 410 and read data from the memory sub-system 410.

The host system 420 can be coupled to the memory sub-system 410 via a physical host interface. Examples of a physical host interface include a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 420 and the memory sub-system 410. The host system 420 can further utilize an NVM Express (NVMe) interface to access components (e.g., memory devices 430) when the memory sub-system 410 is coupled with the host system 420 by the physical host interface (e.g., PCIe bus). The physical host interface can provide an interface for passing control, address, data, and other signals between the memory sub-system 410 and the host system 420. FIG. 4A illustrates a memory sub-system 410 as an example. In general, the host system 420 can access multiple memory sub-systems via a same communication connection, multiple separate communication connections, and/or a combination of communication connections.

The memory devices 430, 440 can include any combination of the different types of non-volatile memory devices and/or volatile memory devices. The volatile memory devices (e.g., memory device 440) can be random access memory (RAM), such as dynamic random access memory (DRAM) and synchronous dynamic random access memory (SDRAM).

Some examples of non-volatile memory devices (e.g., memory device 430) include a negative-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 430 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 430 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 430 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 430 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, or electrically erasable programmable read-only memory (EEPROM).

A memory sub-system controller 415 (or controller 415 for simplicity) can communicate with the memory devices 430 to perform operations such as reading data, writing data, or erasing data at the memory devices 430 and other such operations. The memory sub-system controller 415 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 415 can be a microcontroller, special purpose logic circuitry (e.g., a field programmable gate array (FPGA), an application specific integrated circuit (ASIC), etc.), or other suitable processor.

The memory sub-system controller 415 can include a processing device, which includes one or more processors (e.g., processor 417), configured to execute instructions stored in a local memory 419. In the illustrated example, the local memory 419 of the memory sub-system controller 415 includes an embedded memory configured to store instructions for performing various processes, operations, logic flows, and routines that control operation of the memory sub-system 410, including handling communications between the memory sub-system 410 and the host system 420.

In some embodiments, the local memory 419 can include memory registers storing memory pointers, fetched data, etc. The local memory 419 can also include read-only memory (ROM) for storing micro-code. While the example memory sub-system 410 in FIG. 4A has been illustrated as including the memory sub-system controller 415, in another embodiment of the present disclosure, a memory sub-system 410 does not include a memory sub-system controller 415, and can instead rely upon external control (e.g., provided by an external host, or by a processor or controller separate from the memory sub-system).

In general, the memory sub-system controller 415 can receive commands or operations from the host system 420 and can convert the commands or operations into instructions or appropriate commands to achieve the desired access to the memory devices 430. The memory sub-system controller 415 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 430. The memory sub-system controller 415 can further include host interface circuitry to communicate with the host system 420 via the physical host interface. The host interface circuitry can convert the commands received from the host system into command instructions to access the memory devices 430 as well as convert responses associated with the memory devices 430 into information for the host system 420.

The memory sub-system 410 can also include additional circuitry or components that are not illustrated. In some embodiments, the memory sub-system 410 can include a cache or buffer (e.g., DRAM) and address circuitry (e.g., a row decoder and a column decoder) that can receive an address from the memory sub-system controller 415 and decode the address to access the memory devices 430.

In some embodiments, the memory devices 430 include local media controllers 435 that operate in conjunction with memory sub-system controller 415 to execute operations on one or more memory cells of the memory devices 430. An external controller (e.g., memory sub-system controller 415) can externally manage the memory device 430 (e.g., perform media management operations on the memory device 430). In some embodiments, memory sub-system 410 is a managed memory device, which is a raw memory device 430 having control logic (e.g., local media controller 435) on the die and a controller (e.g., memory sub-system controller 415) for media management within the same memory device package. An example of a managed memory device is a managed NAND (MNAND) device.

The memory sub-system 410 includes a memory interface component 413 that can handle interactions of memory sub-system controller 415 with the memory devices of memory sub-system 410, such as memory device 430. For example, memory interface component 413 can receive data from memory device 430, such as data retrieved in response to a read operation or a write operation. In some examples, the memory sub-system controller 415 can include a processor 417 (processing device) configured to execute instructions stored in local memory 419 for performing the operations described herein.

In some embodiments, memory device 430 includes a program manager 434. In some embodiments, local media controller 435 includes at least a portion of program manager 434 and is configured to perform various memory functions. In some embodiments, the program manager 434 is part of the host system 410, an application, or an operating system. Further details with regards to the operations of program manager 434 are described below. In some embodiments, program manager 434 is implemented on memory device 430 using firmware, hardware components, or a combination of the above.

FIG. 4B is a simplified block diagram of a first apparatus, in the form of a memory device 430, in communication with a second apparatus, in the form of a memory sub-system controller 415 of a memory sub-system (e.g., memory sub-system 410 of FIG. 4A), according to an embodiment. In some embodiments, one or more components of memory device 430 may be manufactured according to a method described herein above. Some examples of electronic systems include personal computers, personal digital assistants (PDAs), digital cameras, digital media players, digital recorders, games, appliances, vehicles, wireless devices, mobile telephones and the like. The memory sub-system controller 415 (e.g., a controller external to the memory device 430), can be a memory controller or other external host device.

Memory device 430 includes an array of memory cells 404 logically arranged in rows and columns. Memory cells of a logical row are typically connected to the same access line (e.g., a wordline) while memory cells of a logical column are typically selectively connected to the same data line (e.g., a bit line). A single access line can be associated with more than one logical row of memory cells and a single data line can be associated with more than one logical column. Memory cells (not shown in FIG. 4B) of at least a portion of array of memory cells 404 are capable of being programmed to one of at least two target data states.

Row decode circuitry 408 and column decode circuitry 411 are provided to decode address signals. Address signals are received and decoded to access the array of memory cells 404. Memory device 430 also includes input/output (I/O) control circuitry 412 to manage input of commands, addresses and data to the memory device 430 as well as output of data and status information from the memory device 430. An address register 414 is in communication with I/O control circuitry 412 and row decode circuitry 408 and column decode circuitry 411 to latch the address signals prior to decoding. A command register 424 is in communication with I/O control circuitry 412 and local media controller 435 to latch incoming commands.

A controller (e.g., the local media controller 435 internal to the memory device 430) controls access to the array of memory cells 404 in response to the commands and generates status information for the external memory sub-system controller 415, i.e., the local media controller 435 is configured to perform access operations (e.g., read operations, programming operations and/or erase operations) on the array of memory cells 404. The local media controller 435 is in communication with row decode circuitry 408 and column decode circuitry 411 to control the row decode circuitry 408 and column decode circuitry 411 in response to the addresses. In at least one embodiment, local media controller 435 includes program manager 434, which can implement the bad block mapping operations with respect to memory device 430, as described herein.

The local media controller 435 is also in communication with a cache register 418. Cache register 418 latches data, either incoming or outgoing, as directed by the local media controller 435 to temporarily store data while the array of memory cells 404 is busy writing or reading, respectively, other data. During a programming operation (e.g., a write operation), data can be passed from the cache register 418 to the data register 421 for transfer to the array of memory cells 404; then new data can be latched in the cache register 418 from the I/O control circuitry 412. During a read operation, data can be passed from the cache register 418 to the I/O control circuitry 412 for output to the memory sub-system controller 415; then new data can be passed from the data register 421 to the cache register 418. The cache register 418 and/or the data register 421 can form (e.g., can form a portion of) a page buffer of the memory device 430. A page buffer can further include sensing devices (not shown in FIG. 4B) to sense a data state of a memory cell of the array of memory cells 404, e.g., by sensing a state of a data line connected to that memory cell. A status register 422 can be in communication with I/O control circuitry 412 and the local memory controller 435 to latch the status information for output to the memory sub-system controller 415.

Memory device 430 receives control signals at the memory sub-system controller 415 from the local media controller 435 over a control link 432. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) can be further received over control link 432 depending upon the nature of the memory device 430. In at least one embodiment, memory device 430 receives command signals (which represent commands), address signals (which represent addresses), and data signals (which represent data) from the memory sub-system controller 415 over a multiplexed input/output (I/O) bus 436 and outputs data to the memory sub-system controller 415 over I/O bus 436.

For example, the commands can be received over input/output (I/O) pins [7:0] of I/O bus 436 at I/O control circuitry 412 and can then be written into command register 424. The addresses can be received over input/output (I/O) pins [7:0] of I/O bus 436 at I/O control circuitry 412 and can then be written into address register 414. The data can be received over input/output (I/O) pins [7:0] for an 8-bit device or input/output (I/O) pins [15:0] for a 16-bit device at I/O control circuitry 412 and then can be written into cache register 418. The data can be subsequently written into data register 421 for programming the array of memory cells 404.

In at least one embodiment, cache register 418 can be omitted, and the data can be written directly into data register 421. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 430 by an external device (e.g., the memory sub-system controller 415), such as conductive pads or conductive bumps as are commonly used.

In some implementations, additional circuitry and signals can be provided, and that the memory device 430 of FIG. 4B has been simplified. It should be recognized that the functionality of the various block components described with reference to FIG. 4B cannot necessarily be segregated to distinct components or component portions of an integrated circuit device. For example, a single component or component portion of an integrated circuit device could be adapted to perform the functionality of more than one block component of FIG. 4B. Alternatively, one or more components or component portions of an integrated circuit device could be combined to perform the functionality of a single block component of FIG. 4B. Additionally, while specific I/O pins are described for receipt and output of the various signals, it is noted that other combinations or numbers of I/O pins (or other I/O node structures) can be used in the various embodiments.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular embodiments may vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A method, comprising:
forming one or more layers of an electronic circuit, the one or more layers comprising a first metal contact isolated by a trench filled with a first dielectric material from a second metal contact;
forming a first recess in the first metal contact;
forming a second recess in the second metal contact;
forming a cap layer by filling the first recess and the second recess with a second dielectric material;
removing a portion of the cap layer to form a first top surface of the one or more layers; and
removing the first dielectric material from the trench to form an open trench between the first metal contact and the second metal contact.

2. The method of claim 1, further comprising:
patterning a mask material on top of the one or more layers, wherein the one or more layers comprises a first hole filled with first dielectric material and a second hole filled with first dielectric material;
etching a top surface of the one or more layers according to the patterned mask material to expose the first hole filled with first dielectric material and the second hole filled with first dielectric material;
removing the first dielectric material from the first hole and from the second hole to form a first void and a second void within the one or more layers; and
filling the first hole and the second hole with a metal to form the first metal contact and the second metal contact.

3. The method of claim 2, further comprising:
removing a portion of the metal to form a second top surface of the one or more layers.

4. The method of claim 1, wherein the cap layer is formed with an overburden, wherein the overburden is removed, and wherein removing the overburden exposes the dielectric material filling the trench.

5. The method of claim 1, wherein removing the portion of the cap layer comprises performing a chemical-mechanical planarization process with respect to the cap layer.

6. The method of claim 1, wherein forming the first recess and the second recess comprises performing a hot phosphorous etch process with respect to the first metal contact and the second metal contact.

7. The method of claim 1, wherein the first metal contact and the second metal contact comprise tungsten.

8. The method of claim 1, wherein the dielectric material comprises a metalloid, and wherein the cap layer comprises a metalloid oxide.

9. The method of claim 1, wherein the electronic circuit comprises a memory array, and wherein the open trench separates a first block of the memory array from a second block of the memory array.

10. A memory array, comprising:
a stack of layers;
a plurality of metal contacts formed within the stack of layers, wherein each of the plurality of metal contacts comprise at least a trace amount of a metalloid oxide adjacent to a first metal contact of the multiple metal contacts; and
a trench formed between at least two of the plurality of metal contacts, wherein the trench is filled with a dielectric material.

11. The memory array of claim 10, wherein a region adjacent to the first metal contact forms (i) a dummy contact, or (ii) a transition region between the first metal and a second metal.

12. The memory array of claim 10, wherein the plurality of metal contacts have a substantially non-flared profile at a region adjacent to the first metal contact.

13. The memory array of claim 10, wherein the at least a trace amount of the metalloid oxide is disposed in a region adjacent to the first metal, the region having a thickness between approximately 150 nanometers and approximately 250 nanometers.

14. The memory array of claim 10, wherein the trench is filled with a metalloid and a metalloid oxide, and wherein an interface between the metalloid and the metalloid oxide forms a dished region.

15. A method, comprising:
forming a first metal contact and a second metal contact within one or more layers of an electronic circuit;
forming a trench between the first metal contact and the second metal contact;
filling the trench with a first dielectric material;
forming a first recess in the first metal contact;
forming a second recess in the second metal contact;
forming a cap layer by filling the first recess and the second recess with a second dielectric material, wherein the first metal contact and the second metal contact each comprise at least a trace amount of a metalloid oxide adjacent to a first metal of the first metal contact and of the second metal contact; and
removing the first dielectric material from the trench to form an open trench between the first metal contact and the second metal contact.

16. The method of claim 15, further comprising:
patterning a mask material on top of the one or more layers, wherein the one or more layers comprises a first hole filled with first dielectric material and a second hole filled with first dielectric material;
etching a top surface of the one or more layers according to the patterned mask material to expose the first hole filled with first dielectric material and a second hole filled with first dielectric material;
removing the first dielectric material from the first hole and from the second hole to form a first void and a second void within the one or more layers; and
filling the first hole and the second hole with a metal to form the first metal contact and the second metal contact.

17. The method of claim 15, further comprising:
removing a portion of the cap layer to form a top surface of the one or more layers.

18. The method of claim 17, wherein removing the portion of the cap layer comprises performing a chemical-mechanical planarization process with respect to the cap layer.

19. The method of claim 15, wherein the first metal contact and the second metal contact comprise tungsten, wherein the dielectric material comprises a metalloid, and wherein the cap layer comprises a metalloid oxide.

20. The method of claim 15, wherein the electronic circuit comprises a memory array, and wherein the open trench separates a first block of the memory array from a second block of the memory array.
